(19) United States
(12) Patent Application Publication
(10) Pub. No.: US 2020/0150894 A1
(43) Pub. Date: May 14, 2020

(54) MEMORY DEVICE INCLUDING A RANDOM INPUT AND OUTPUT ENGINE AND A STORAGE DEVICE INCLUDING THE MEMORY DEVICE

(71) Applicant: Samsung Electronics Co., Ltd., Suwon-Si (KR)

(72) Inventors: SANG-KIL LEE, Seongnam-si (KR); Chang-kyu Seol, Osan-si (KR); Dae-hyun Kim, Suwon-si (KR); Jin-min Kim, Seoul (KR); Hei-seung Kim, Suwon-si (KR); Hyun-mog Park, Seoul (KR); Hyun-sik Park, Seoul (KR); Hak-yong Lee, Gunpo-si (KR)

(21) Appl. No.: 16/532,575

(22) Filed: Aug. 6, 2019

(30) Foreign Application Priority Data
Nov. 13, 2018 (KR) 10-2018-0139395

(51) Int. Cl. G06F 3/06; G11C 11/56; H01L 25/18

(52) U.S. Cl. CPC G06F 3/0655; G11C 11/5628; G11C 11/5642; H01L 25/18; H01L 27/11556; G06F 3/061; G06F 3/0619; G06F 3/0679; G11C 11/5671

(57) ABSTRACT

A storage device including: a memory controller configured to output user data received from outside of the storage device in a write operation mode and receive read data in a read operation mode; and a memory device including a memory cell array and a random input and output (I/O) engine, the random I/O engine configured to encode the user data provided from the memory controller using a random I/O code, in the write operation mode, and to generate the read data by decoding internal read data read by a data I/O circuit from the memory cell array using the random I/O code, in the read operation mode.

### CROSS-REFERENCE TO RELATED PATENT APPLICATION

This application claims priority under 35 U.S.C. § 119 to Korean Patent Application No. 10-2018-0139395, filed on Nov. 13, 2018, in the Korean Intellectual Property Office, the disclosure of which is incorporated by reference herein in its entirety.

### TECHNICAL FIELD

The inventive concept relates to a memory device and a storage device, and more particularly, to a non-volatile memory device including a random input and output (I/O) engine, and a storage device including the non-volatile memory device.

### DISCUSSION OF RELATED ART

Semiconductor memory devices may be volatile memory devices that lose stored data in the absence of power or non-volatile memory devices that do not lose stored data when power is lost. Volatile memory devices read and write data fast, but lose stored contents when their power supply is interrupted. Non-volatile memory devices read and write data slow compared to volatile memory devices, but retain stored contents when their power supply is interrupted.

A flash memory device is an example of a non-volatile memory device. In a flash memory device, as the number of bits of data stored in one memory cell increases, a time period taken to read data from the memory device also increases. The increase in a data read-out time period may reduce the speed of memory devices.

### SUMMARY

According to an exemplary embodiment of the inventive concept, there is provided a storage device including a memory controller configured to output user data received from outside of the storage device in a write operation mode and receive read data in a read operation mode; and a memory device including a memory cell array and a random input and output (I/O) engine, the random I/O engine configured to encode the user data provided from the memory controller using a random I/O code, in the write operation mode, and to generate the read data by decoding internal read data read by a data I/O circuit from the memory cell array using the random I/O code, in the read operation mode.

According to another exemplary embodiment of the inventive concept, there is provided a memory device including a plurality of layers, the memory device including a first layer including a plurality of memory cells; and a second layer including a control logic unit and a random I/O engine, wherein the random I/O engine includes: a random I/O encoder configured to encode user data received from outside of the memory device using a random I/O code; and a random I/O decoder configured to decode internal read data obtained from the memory device using the random I/O code.

According to another exemplary embodiment of the inventive concept, there is provided a storage device including a memory device including a memory cell array including a plurality of memory cells, and a peripheral circuit region spatially separated from the memory cell array; and a memory controller configured to control an operation of the memory device, wherein the memory device includes a random I/O engine formed on the peripheral circuit region and configured to encode data received from the memory controller and decode data that is to be transmitted to the memory controller.

According to an exemplary embodiment of the inventive concept, a method of operating a storage device includes: receiving, at a memory controller, first data from a first source; generating, at a memory device, encoded data by performing a random I/O encoding on the first data; and writing, at the memory device, the encoded data to a memory cell array.

### BRIEF DESCRIPTION OF THE DRAWINGS

The above and other features of the inventive concept will be more clearly understood by describing in detail exemplary embodiments thereof with reference to the accompanying drawings in which:

FIG. 1 is a block diagram of a data processing system according to an exemplary embodiment of the inventive concept;

FIG. 2 is a block diagram of a memory device according to an exemplary embodiment of the inventive concept;

FIGS. 3A and 3B illustrate a structure of a memory block according to an exemplary embodiment of the inventive concept;

FIG. 4 is a graph showing a threshold voltage distribution of memory cells according to an exemplary embodiment of the inventive concept;

FIG. 5 is a block diagram of a memory controller and a memory device according to an exemplary embodiment of the inventive concept;

FIGS. 6A and 6B illustrate data and encoded data according to an exemplary embodiment of the inventive concept, respectively;

FIG. 7 illustrates a wafer bonding coupling structure of a memory device according to an exemplary embodiment of the inventive concept;

FIG. 8 illustrates a wafer bonding coupling structure of a memory device according to an exemplary embodiment of the inventive concept;

FIG. 9 is a perspective view illustrating a Cell-on-Peri (COP) structure of a memory device according to an exemplary embodiment of the inventive concept;

FIG. 10 is a cross-sectional view illustrating a COP structure of a memory device according to an exemplary embodiment of the inventive concept;

FIGS. 11A, 1113B and 11C are cross-sectional views of a first layer of a memory device according to an exemplary embodiment of the inventive concept;

FIG. 12 is a flowchart of a data write operation of a storage device, according to an exemplary embodiment of the inventive concept;

FIG. 13 is a flowchart of a data read operation of a storage device, according to an exemplary embodiment of the inventive concept;

FIG. 14 is a block diagram of a data processing system according to an exemplary embodiment of the inventive concept; and

FIG. 15 is a block diagram of a Solid State Drive/Disk (SSD) according to an exemplary embodiment of the inventive concept.

### DETAILED DESCRIPTION OF THE EMBODIMENTS

Hereinafter, exemplary embodiments of the inventive concept will be described more fully with reference to the accompanying drawings.

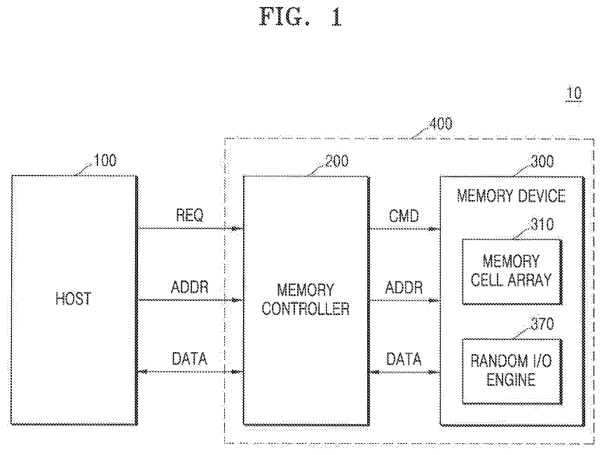

FIG. 1 is a block diagram of a data processing system 10 according to an exemplary embodiment of the inventive concept. The data processing system 10 may include a host 100 and a memory system 400. The memory system 400 may include a memory controller 200 and a memory device 300. The data processing system 10 is applicable to one of various computing systems, such as ultra mobile personal computers (UMPCs), workstations, net books, personal digital assistants (PDAs), portable computers, web tablets, wireless phones, mobile phones, smart phones, e-books, portable multimedia players (PMPs), portable game players, navigation devices, black boxes, and digital cameras.

Each of the host 100, the memory controller 200, and the memory device 300 may be provided as a single chip, a single package, or a single module. However, the inventive concept is not limited thereto. For example, the memory controller 200 may be provided as the memory system 400 or a storage device, together with the memory device 300. The host 100 may be provided on a chip separate from the memory controller 200 and the memory device 300.

The memory system 400 may constitute a PC card (e.g., the personal computer memory card international association (PCMCIA)), a compact flash (CF) card, a smart media card (SM/SMC), a memory stick, a multi-media card (MMC) (e.g., a reduced size MMC (RS-MMC) or a MMCmicro), a secure digital (SD) card (e.g., a mini-SD card or a micro-SD card), or a universal flash storage (UFS). As another example, the memory system 400 may constitute a Solid State Drive/Disk (SSD).

The host 100 may transmit a data operation request REQ and an address ADDR to the memory controller 200 and may transmit and/or receive data DATA to and/or from the memory controller 200. For example, the host 100 may exchange the data DATA with the memory controller 200, based on at least one of various interface protocols, such as a Universal Serial Bus (USB) protocol, a Multi Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, a Mobile Industry Processor Interface (MIPI) protocol, and a UFS protocol.

The memory controller 200 may control the memory device 300. For example, the memory controller 200 may control the memory device 300 such that the data DATA is read out of the memory device 300 or is written to the memory device 300, in response to the data operation request REQ received from the host 100. For example, the memory controller 200 may provide the memory device 300 with the address ADDR, a command CMD, and a control signal to control a write operation, a read operation, and an erase operation on the memory device 300. The data DATA for the write, read and erase operations may be transmitted and/or received between the memory controller 200 and the memory device 300.

The memory device 300 may include at least one memory cell array 310. The memory cell array 310 may include a plurality of memory cells that are disposed at intersections of a plurality of bit lines and a plurality of word lines, and the plurality of memory cells may be non-volatile memory cells. Each memory cell may be a multi-level cell that stores two or more bits of data. For example, each memory cell may be a 2-bit multi-level cell that stores two bits of data, a triple-level cell (TLC) that stores three bits of data, a quad-level cell (QLC) that stores four bits of data, or a multi-level cell that stores more than four bits of data. However, the inventive concept is not limited thereto. For example, some memory cells may be single-level cells (SLCs) each storing one bit of data, and other memory cells may be multi-level cells. The memory device 300 may include a NAND flash memory, a vertical NAND (VNAND) flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or a combination thereof. The memory device 300 may perform operations, such as a write operation, a read operation, and an erase operation, on the data DATA, in response to signals received from the memory controller 200.

In the present specification, for convenience of explanation, a write operation mode of the memory system 400 may correspond to when the memory controller 200 controls a write operation of the memory device 300, based on the data operation request REQ of the host 100, and the memory device 300 performs a write operation under the control of the memory controller 200. Additionally, a read operation mode of the memory system 400 may correspond to when the memory controller 200 controls a read operation of the memory device 300, based on the data operation request REQ of the host 100, and the memory device 300 performs a read operation under the control of the memory controller 200.

The memory device 300 may include a random input and output (I/O) engine 370. The random I/O engine 370 may encode data input to the memory device 300 by using a random I/O code, or may decode data output by the memory device 300 by using the random I/O code. Since the memory device 300 stores encoded data obtained using the random I/O code, even when the memory cells included in the memory cell array 310 are multi-level cells storing two or more bits of data, the memory device 300 may read stored data via only one sensing operation or a small number of sensing operations. According to an exemplary embodiment of the inventive concept, the random I/O code may be an error correction code (ECC) for correcting an error. According to an exemplary embodiment of the inventive concept, the random I/O engine 370 may include a random I/O encoder that performs encoding by using the random I/O code, and a random I/O decoder that performs decoding by using the random I/O code. The random I/O decoder may decode data stored in a memory cell and also may perform error correction by using an ECC. For convenience of explanation, the encoding by the random I/O engine 370 by using the random I/O code may be referred to as random I/O encoding, and the decoding by the random I/O engine 370 by using the random I/O code may be referred to as random I/O decoding. Operations of the random I/O engine 370 will be described in more detail with reference to the drawings below.

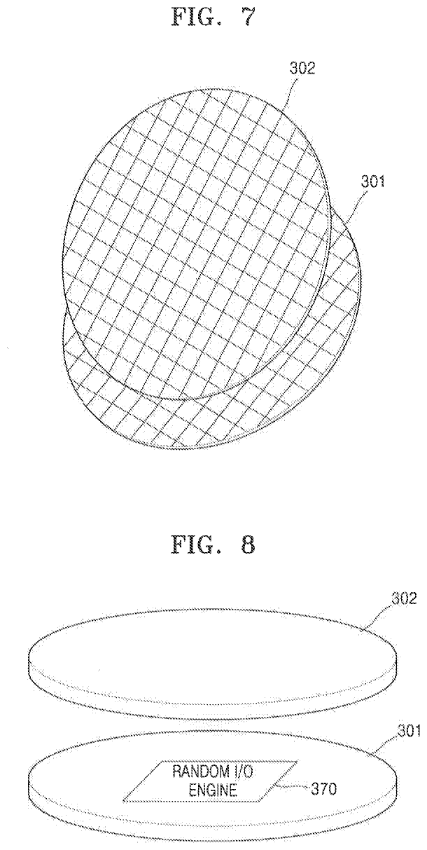

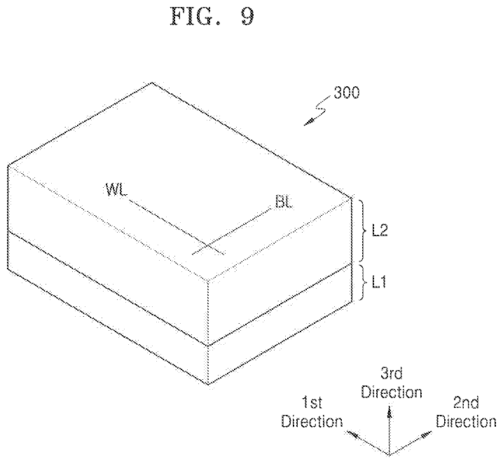

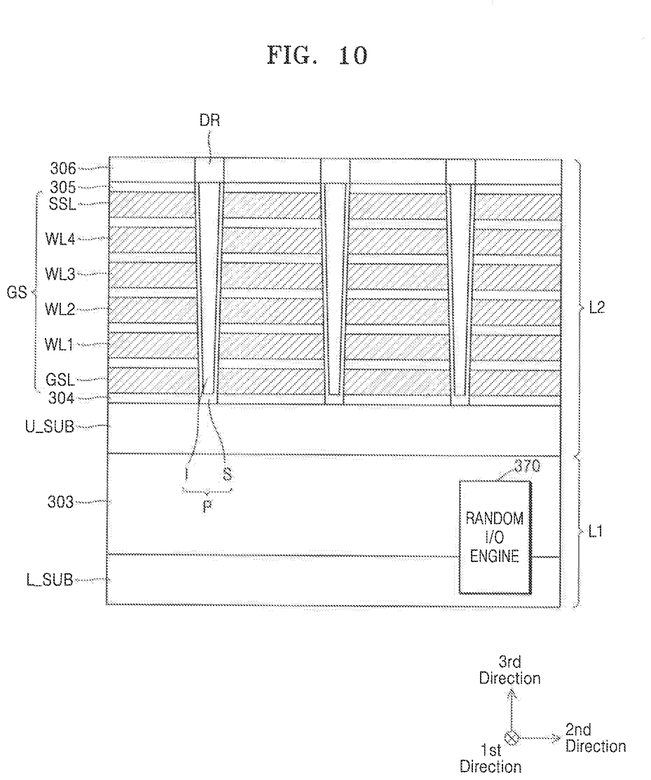

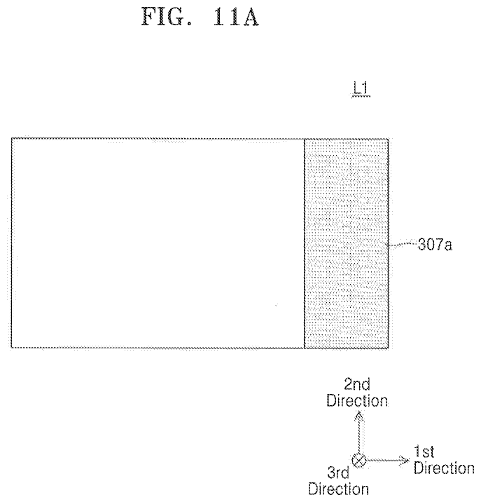

The memory device 300 may include a peripheral circuit region that is spatially separated from the memory cell array 310 and includes peripheral circuits. The random I/O engine 370 may be formed in the peripheral circuit region. According to an exemplary embodiment of the inventive concept, the memory device 300 may have a structure in which a first wafer including the memory cell array 310 and a second wafer including a peripheral circuit bond to each other via wafer bonding. The random I/O engine 370 may be formed on the second wafer. According to an exemplary embodiment of the inventive concept, the memory device 300 may have a Cell-on-Peri or Cell-over-Peri (COP) structure in which a second wafer including the memory cell array 310 is stacked on a first wafer including a peripheral circuit, and the random I/O engine 370 may be formed on the first wafer. The wafer bonding structure of the memory device 300 will be described in more detail with reference to FIGS. 7 and 8. In addition, the COP structure of the memory device 300 will be described in more detail with reference to FIGS. 9 and 10.

In general data processing systems, a memory system may not include a random I/O engine. Further, even when the memory system includes a random I/O engine, the random I/O engine is implemented in a memory controller. This is so, because the random I/O engine occupies a large space. Accordingly, in general data processing systems, when encoded data or not-yet decoded data is transmitted and/or received between the memory controller and the memory device, the encoded data has a larger capacity than the not-yet encoded data. Since a large amount of data is transmitted and/or received, in a data read mode, a time period tDMA taken to transmit data from the memory device to the memory controller increases.

In the data processing system 10 according to an exemplary embodiment of the inventive concept, the random I/O engine 370 may be implemented in the memory device 300. In particular, the memory device 300 has a structure in which a layer (or a wafer or a chip) including the memory cell array 310 thereon and a layer (or a wafer or a chip) including a peripheral circuit thereon are stacked on each other. Accordingly, the layer including the peripheral circuit has a free region where the random I/O engine 370 can be formed, and consequently, the random I/O engine 370 may be implemented in the memory device 300. The representative example described herein is an example in which the memory device 300 has a wafer bonding structure or a COP structure.

In the data processing system 10 according to an exemplary embodiment of the inventive concept, because the memory device 300 includes the random I/O engine 370, the data transmitted and/or received between the memory controller 200 and the memory device 300 may be not-encoded data. Thus, compared with general data processing systems, the data transmitted and/or received between the memory controller 200 and the memory device 300 may have a reduced capacity.

Accordingly, a time period during which data is transmitted from the memory device 300 to the memory controller 200 may also be reduced, and consequently, a time period taken for the memory system 400 to perform data reading may be reduced. Moreover, as the capacity of the data transmitted and/or received between the memory controller 200 and the memory device 300 is decreased, the power efficiency of the memory system 400 and/or the data processing system 10 may be increased.

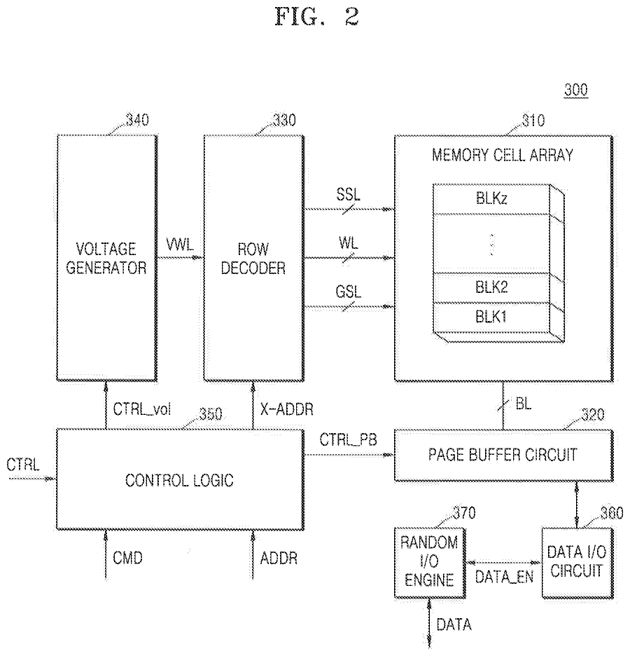

FIG. 2 is a block diagram of the memory device 300 according to an exemplary embodiment of the inventive concept. A description of the memory device 300 of FIG. 2 that is the same as that given above with reference to FIG. 1 will not be repeated herebelow.

The memory device 300 may include a memory cell array 310, a page buffer circuit 320, a row decoder 330, a voltage generator 340, a control logic unit 350, a data I/O circuit 360, and the random I/O engine 370.

The memory cell array 310 may include a plurality of memory blocks BLK1 through BLKz. Each of the plurality of memory blocks BLK1 through BLKz may include a plurality of memory cells. The memory cell array 310 may be connected to the row decoder 330 via word lines WL, string select lines SSL, and ground select lines GSL, and may be connected to the page buffer circuit 320 via bit lines BL. The memory cell array 310 may include strings respectively connected to the bit lines BL. Each of the strings may include at least one string select transistor, a plurality of memory cells, and at least one ground select transistor serially connected between each bit line BL and a common source line.

The page buffer circuit 320 may be connected to the memory cell array 310 through the bit lines BL and may perform a data write operation or a data read operation in response to a page buffer control signal CTRL_PB received from the control logic unit 350. The page buffer circuit 320 may be connected to a data line by selecting a bit line BL by using a decoded column address.

The row decoder 330 may select some of the word lines WL, based on a row address X-ADDR. The row decoder 330 may transmit a word line apply voltage to a word line WL. For example, during a data write operation, the row decoder 330 may apply a program voltage and a verify voltage to a selected word line WL and apply a program inhibit voltage to unselected word lines WL. During a data read operation, the row decoder 330 may apply a read voltage to a selected word line WL and apply a read inhibit voltage to unselected word lines WL. During a data erase operation, the row decoder 330 may apply a word line erase voltage to a word line WL. The row decoder 330 may also select some of the string select lines SSL or some of the ground select lines GSL in response to the row address X-ADDR.

The voltage generator 340 may generate various types of voltages for executing a write operation, a read operation, and an erase operation with respect to the memory cell array 310, based on a voltage control signal CTRL_vol received from the control logic unit 350. For example, the voltage generator 340 may generate a word line drive voltage VWL for driving the word lines WL. The word line drive voltage VWL may include a write voltage, a read voltage, a word line erase voltage, and a write verify voltage. The voltage generator 340 may further generate a string select line drive voltage for driving the string select lines SSL, and a ground select line drive voltage for driving the ground select lines GSL.

The control logic unit 350 may receive a command CMD, an address ADDR, and a control signal CTRL from a memory controller and generate various internal control signals for writing data to the memory cell array 310 or for reading data from the memory cell array 310, based on the received command CMD, the received address ADDR, and the received control signal CTRL. In other words, the control logic unit 350 may control various operations performed in the memory device 300. The various internal control signals generated by the control logic unit 350 may be provided to the page buffer circuit 320, the row decoder 330, and the voltage generator 340. For example, the control logic unit 350 may provide the page buffer control signal CTRL_PB to the page buffer circuit 320, the row address X_ADDR to the row decoder 330, and the voltage control signal CTRL_vol to the voltage generator 340. However, the types of control signals are not limited thereto, and the control logic unit 350 may generate and output various other internal control signals. For example, the control logic unit 350 may provide a column address to a column decoder.

The data I/O circuit 360 may be connected to the page buffer circuit 320 via data lines and may provide data received from the random I/O engine 370 to the page buffer circuit 320 or provide data received from the page buffer circuit 320 to the random I/O engine 370.

The random I/O engine 370 may encode the data DATA input to the memory device 300 by using the random I/O code, or may decode the data DATA output by the memory device 300 by using the random I/O code. An operation of the random I/O engine 370 in each of the write operation mode and the read operation mode will now be described.

In the write operation mode, the random I/O engine 370 may generate encoded data DATA_EN by encoding the data DATA provided from outside the memory device 300 by using the random I/O code and may provide the encoded data DATA_EN to the data I/O circuit 360. A capacity of the encoded data DATA_EN may be greater than that of the data DATA. According to an exemplary embodiment of the inventive concept, the encoded data DATA_EN may include the data DATA and a random I/O parity. The encoded data DATA_EN may further include an ECC parity.

In the read operation mode, the data I/O circuit 360 may receive data obtained from the memory cell array 310 from the page buffer circuit 320. For convenience of explanation, the data obtained by the data I/O circuit 360 is referred to as internal read data. The internal read data may be the encoded data DATA_EN. However, the internal read data may include a bit error generated due to a charge loss and/or a read disturbance, compared with the encoded data DATA_EN at the time when the internal read data is written. The random I/O engine 370 may generate read data by decoding the internal read data provided by the data I/O circuit 360 by using the random I/O code. In other words, the random I/O engine 370 may restore the data DATA by performing error correction while decoding the encoded data DATA_EN provided as the internal read data by using the random I/O code and may output the restored data DATA as the read data.

The random I/O engine 370 may be implemented in various forms within a memory device. The random I/O engine 370 may be implemented as hardware or software. For example, when the random I/O engine 370 is implemented as hardware, the random I/O engine 370 may include circuits for performing encoding and decoding by using the random I/O code. For example, when the random I/O engine 370 is implemented as software, a program (or instructions) stored in the memory device 300 and/or the random I/O code may be executed by at least one processor included in the control logic unit 350 or the memory device 300, and thus, the random I/O engine 370 may perform encoding and decoding. However, the inventive concept is not limited to the above-described embodiments, and the random I/O engine 370 may be implemented as a combination of hardware and software, like firmware.

In the memory device 300 according to an exemplary embodiment of the inventive concept, since the memory cell array 310 stores encoded data obtained by the random I/O engine 370, the memory device 300 may read stored data only via one sensing operation or a small number of sensing operations. In addition, since the data DATA received or output by the memory device 300 is not-encoded data, the capacity of data transmitted and/or received by the memory device 300 to an external memory controller may be reduced. Accordingly, a time period taken to read data from the memory device 300 may decrease, and power efficiency of a memory system may increase.

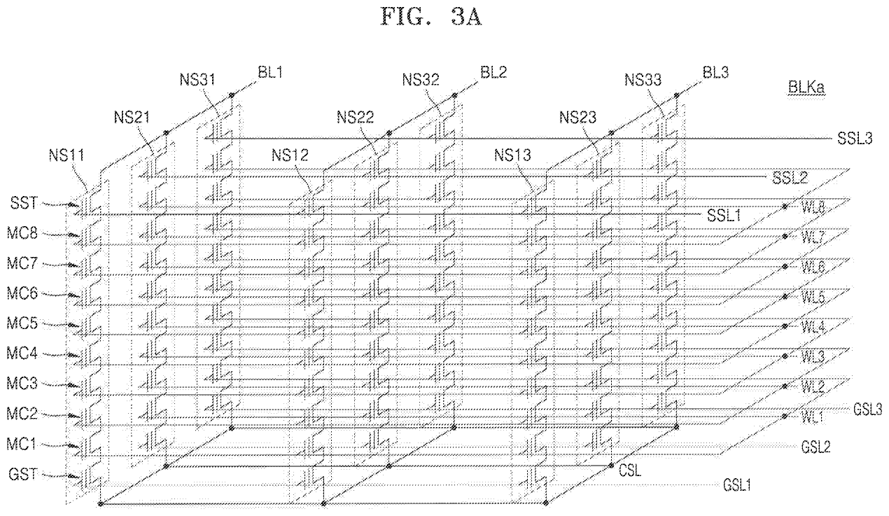

FIGS. 3A and 3B illustrate a structure of a memory block BLKa according to an exemplary embodiment of the inventive concept. Each of the plurality of memory blocks BLK1 through BLKz included in the memory cell array 310 of FIG. 2 may have the structure of the memory block BLKa of FIG. 3A and/or FIG. 3B.

Referring to FIG. 3A, the memory block BLKa may include a plurality of NAND strings NS11, NS21, NS31, NS12, NS22, NS32, NS13, NS23, and NS33, a plurality of ground select lines GSL1, GSL2, and GSL3, a plurality of string select lines SSL1, SSL2, and SSL3, and a common source line CSL. The number of NAND strings, the number of word lines WL, the number of bit lines BL, the number of ground select lines GSL, and the number of string select lines SSL may vary according to the embodiments of the inventive concept.

The NAND strings NS11, NS21, and NS31 may be provided between a first bit line BL1 and the common source line CSL. The NAND strings NS12, NS22, and NS32 may be provided between a second bit line BL2 and the common source line CSL. The NAND strings NS13, NS23, and NS33 may be provided between a third bit line BL3 and the common source line CSL. Each (for example, NS11) of the NAND strings NS11, NS21, NS31, NS12, NS22, NS32, NS13, NS23, and NS33 may include a string select transistor SST, a plurality of memory cells MC1, MC2, MC3, MC4, MC5, MC6, MC7 and MC8, and a ground select transistor GST that are serially connected to each other.

The string select transistors SST may be connected to the corresponding string select lines SSL1 through SSL3. The memory cells MC1 through MC8 may be connected to word lines WL1, WL2, WL3, WL4, WL5, WL6, WL7 and WL8, respectively. The ground select transistors GST may be connected to the corresponding ground select lines GSL1 through GSL3. The string select transistors SST may be connected to the corresponding bit lines BL1 through BL3, and the ground select transistors GST may be connected to the common source line CSL.

Although each string includes a single string select transistor SST in FIG. 3A, the inventive concept is not limited thereto. Each string may include an upper string select transistor and a lower string select transistor serially connected to each other. Although each string includes a single ground select transistor GST in FIG. 3A, the inventive concept is not limited thereto. Each string may include an upper ground select transistor and a lower ground select transistor serially connected to each other. In this case, the upper ground select transistors may be connected to the corresponding ground select lines GSL1 through GSL3, and the lower ground select transistors may be commonly connected to a common ground select line.

Referring to FIG. 3B, the memory block BLKa may be formed in a vertical direction (e.g., a third direction) with respect to a substrate SUB (or an upper substrate). Although the memory block BLKa includes two select lines GSL and SSL, eight word lines WL1 through WL8, and three bit lines BL1, BL2, and BL3 in FIG. 3B, the numbers of select lines SL, word lines WL, and bit lines BL may vary. As another example, the memory block BLKa may include one or more dummy word lines between the first word line WL1 and the ground select line GSL and/or between the eighth word line WL8 and the string select line SSL.

The substrate SUB may be a polysilicon layer doped with impurities of a first conductivity type (for example, a p type). The substrate SUB may be a bulk silicon substrate, a silicon on insulator (SOI) substrate, a germanium substrate, a germanium on insulator (GOI) substrate, a silicon-germanium substrate, or an epitaxial thin-film substrate obtained via selective epitaxial growth (SEG). The substrate SUB may be formed of a semiconductor material and may include, for example, silicon (Si), germanium (Ge), silicon germanium (SiGe), gallium arsenic (GaAs), indium gallium arsenic (InGaAs), aluminum gallium arsenic (AlGaAs), or a mixture thereof.

Common source lines CSL each extending in a second direction and doped with impurities of a second conductivity type (for example, an n type) may be provided on the substrate SUB. On a region of the substrate SUB between two adjacent common source lines CSL, a plurality of insulation layers IL each extending in a first direction are sequentially provided in the third direction. The plurality of insulation layers IL are spaced apart from one another by a certain distance in the third direction. For example, the plurality of insulation layers IL may include an insulative material such as Si oxide.

On regions of the substrate SUB between every two adjacent common source lines CSL, a plurality of pillars P each penetrating through the plurality of insulation layers IL in the third direction are sequentially arranged in the first direction. For example, the plurality of pillars P may penetrate through the plurality of insulation layers IL to thereby contact the substrate SUB. For example, a surface layer S of each pillar P may include a silicon material doped with impurities of the first conductivity type and may function as a channel region. Each pillar P may be referred to as a vertical channel structure. An internal layer I of each pillar P may include an insulative material, such as Si oxide, or an air gap. For example, the size of a channel hole in each pillar P may decrease in a direction toward the substrate SUB. For example, the channel hole may be tapered.

On a region of the substrate SUB between two adjacent common source lines CSL, a charge storage layer CS may be provided along exposed surfaces of the insulation layers IL, the pillars P, and the substrate SUB. The charge storage layer CS may include a gate insulation layer (or a tunnel insulation layer), a charge trapping layer, and a blocking insulation layer. For example, the charge storage layer CS may have an oxide-nitride-oxide (ONO) structure. On the region of the substrate SUB between two adjacent common source lines CSL, a gate electrode GE, such as the select lines GSL and SSL and the word lines WL1 through WL8, may be provided on an exposed surface of the charge storage layer CS.

Drains or drain contacts DR are provided on the plurality of pillars P. For example, the drains or drain contacts DR may include a silicon material doped with impurities of the second conductive type. The bit lines BL1, BL2, and BL3, each extending in the first direction and spaced apart from each other by a certain distance in the second direction, may be provided on the drain contacts DR. The bit lines BL1, BL2, and BL3 may be electrically connected to the drain contacts DR via contact plugs.

A word line cut region extending in the second direction may be provided on each of the common source lines CSL. The gate electrodes GE may be separated from each other by the word line cut regions. For example, the word line cut regions may include an insulative material or may be an air gap.

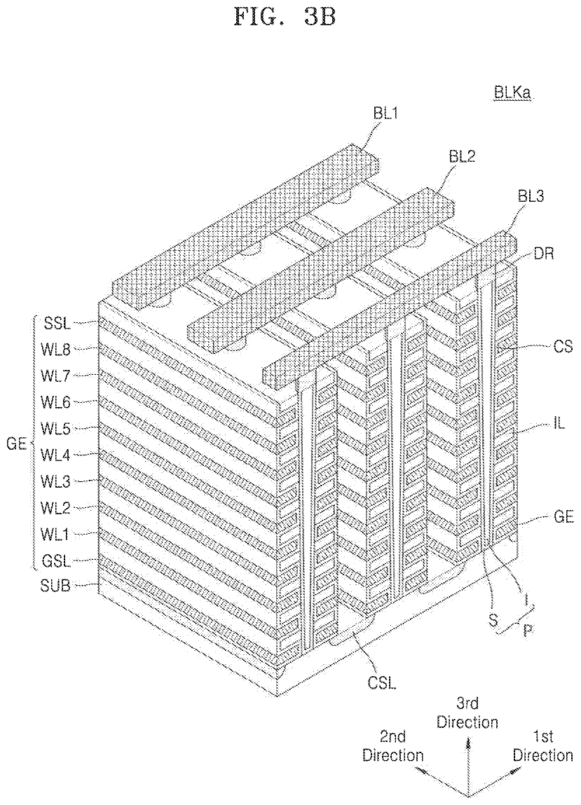

FIG. 4 is a graph showing a threshold voltage distribution of memory cells according to an exemplary embodiment of the inventive concept. In particular, FIG. 4 illustrates a threshold voltage distribution when the memory cells are TLCs each storing 3-bit data.

Referring to FIG. 4, the horizontal axis indicates a threshold voltage Vth of a memory cell and the vertical axis indicates the number of memory cells. Each memory cell may have an erase state E and first through seventh program states P1, P2, P3, P4, P5, P6 and P7. In a direction from the erase state E to the seventh program state P7, more electrons may be injected into a floating gate of each memory cell.

A first read voltage Vr1 may have a voltage level between a distribution of memory cells in the erase state E and a distribution of memory cells in the first program state P1. An i-th read voltage Vri (where i is a natural number ranging between 2 and 7) may have a voltage level between a distribution of memory cells in an (i−1)th program state Pi−1 and a distribution of memory cells in an i-th program state Pi.

The first read voltage Vr1, a second read voltage Vr2, a third read voltage Vr3, a fourth read voltage Vr4, a fifth read voltage Vr5, a sixth read voltage Vr6 and a seventh read voltage Vr7 are read voltages for distinguishing memory cells in different program states from one another.

As such, when a memory cell is a multi-level cell storing two or more bits of data, two or more sensing operations are generally needed to read data from the memory cell. In particular, when a memory cell is a TLC storing 3-bit data, sensing should be performed 2.333 times on average to read data, and, when a memory cell is a QLC storing 4-bit data, sensing should be performed 3.75 times on average to read data.

However, because a memory device according to an exemplary embodiment of the inventive concept includes a random I/O engine, even when each memory cell is a multi-level cell storing two or more bits of data, data may be read from the memory cell via only one sensing operation.

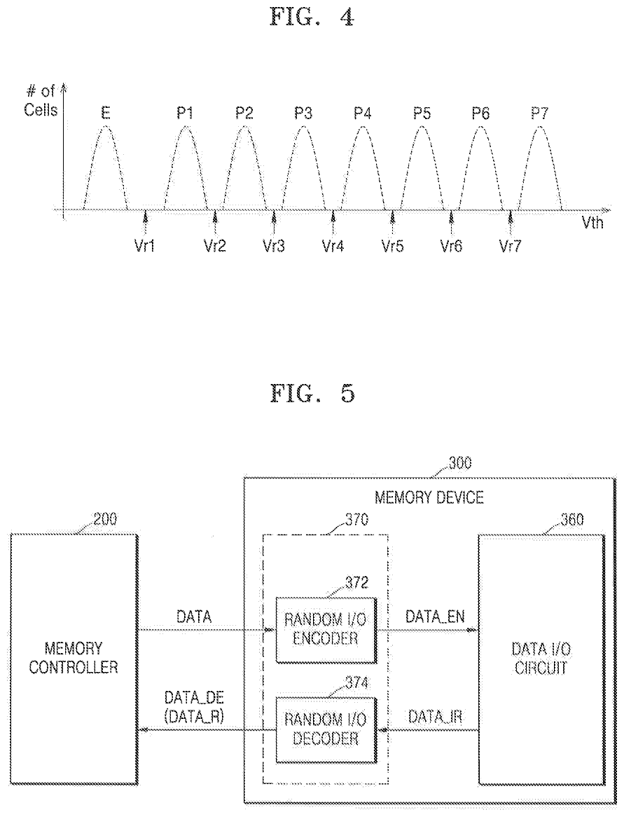

FIG. 5 is a block diagram of the memory controller 200 and the memory device 300 according to an exemplary embodiment of the inventive concept. Descriptions of the memory controller 200 and the memory device 300 of FIG. 5 that are the same as those given above with reference to FIGS. 1 and 2 will not be repeated herebelow.

The random I/O engine 370 may include a random I/O encoder 372 and a random I/O decoder 374.

In the write operation mode, the random I/O encoder 372 may generate the encoded data DATA_EN by encoding the data DATA received from the memory controller 200 by using a data I/O code. The random I/O encoder 372 may provide the encoded data DATA_EN to the data I/O circuit 360, and the data I/O circuit 360 may allow the memory device 300 to write the encoded data DATA_EN to its memory cell array, e.g., memory cell array 310. According to an exemplary embodiment of the inventive concept, random I/O encoding by the random I/O encoder 372 may represent an operation of generating the encoded data DATA_EN in which an ECC parity and a random I/O parity are added to the data DATA. In other words, the random I/O encoding by the random I/O encoder 372 may include an ECC operation. The ECC parity may be parity information that is used in an error correction operation. The random I/O parity may be parity information that is added to the data DATA so that the memory device 300 may read data from a multi-level cell storing two or more bits of data by performing one sensing.

In the read operation mode, the random I/O decoder 374 may generate decoded data DATA_DE by decoding internal read data DATA_IR received from the data I/O circuit 360 by using the data I/O code. In this case, the random I/O decoder 374 may also perform an error correction operation. The random I/O decoder 374 may provide the decoded data DATA_DE as read data DATA_R to the memory controller 200. In other words, the random I/O decoder 374 may restore data by decoding the internal read data DATA_IR, which is encoded data.

The random I/O code may enable the memory device 300 including memory cells each storing two or more bits of data to read data from the memory cells via one sensing operation while correcting (or recovering) a bit error of data stored in the memory device 300. To accomplish this, according to an exemplary embodiment of the inventive concept, the random I/O code may include an ECC and may be implemented using a polar code. The polar code is a code based on a channel deflection phenomenon as described by Erdal Arikan, and is a channel code capable of attaining an information theoretical limitation asserted by Shannon. In the channel deflection phenomenon, a new vector channel obtained by multiplying a matrix capable of making a channel deflection phenomenon occur in front of n independent identically distributed (i.i.d.) channels is divided into a channel capable of completely recovering a signal and a channel unable to recover a signal. As a non-limiting example, the ECC may include a Low Density Parity Check (LDPC) code, a Bose-Chaudhuri-Hocquenghem (BCH) code, a turbo code, a Reed-Solomon code, a convolution code, a Recursive Systemic Code (RSC), and coded modulation, such as Trellis-Coded Modulation (TCM) and Block Coded Modulation (BCM).

According to an exemplary embodiment of the inventive concept, the random I/O code may be modeled via broadcast channel modeling. According to an exemplary embodiment of the inventive concept, modeling of the random I/O code may include a noise-less portion as a deterministic broadcast channel, and a binary channel portion with noise. Encoding based on the random I/O code may be performed via data distinguishing and data mapping methods, and encoding and decoding based on the random I/O code may include a calculation operation with respect to a plurality of posteriori probabilities.

In the memory controller 200 and the memory device 300 according to an exemplary embodiment of the inventive concept, both the data DATA and the read data DATA_R transmitted and/or received between the memory controller 200 and the memory device 300 are not-encoded pieces of data. In other words, respective capacities of the data DATA and the read data DATA_R may be less than those of the encoded data DATA_EN and the internal read data DATA_IR, respectively. Accordingly, as a small capacity of data (for example, a small number of bits of data) is transmitted and/or received between the memory controller 200 and the memory device 300, a data read-out time period may decrease, and power efficiency of a memory system may increase.

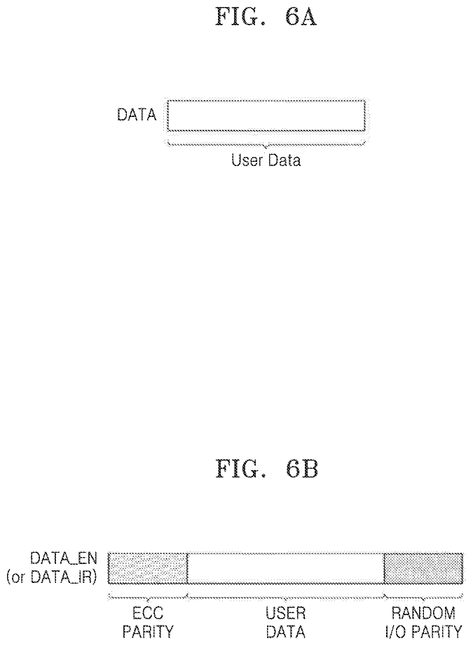

FIGS. 6A and 6B illustrate the data DATA and the encoded data DATA_EN according to an exemplary embodiment of the inventive concept, respectively. FIGS. 6A and 6B will now be described with reference to FIG. 5.

Referring to FIG. 6A, the data DATA may include user data. Referring to FIGS. 1 and 6A, the user data may represent data provided by the host 100 to the memory controller 200. In other words, the data DATA provided by the memory controller 200 to the memory device 300 may be not-encoded user data.

Referring to FIG. 6B, the encoded data DATA_EN or the internal read data DATA_IR may include user data, an ECC parity, and a random I/O parity. The ECC parity may be parity information used by the random I/O decoder 374 to perform error correction on the internal read data DATA_IR. The random I/O parity may be parity information which the memory device 300 uses to read data from a memory cell via only one sensing operation even when the memory cell is a multi-level cell storing two or more bits of data.

Locations of the user data, the ECC parity, and the random I/O parity on the encoded data DATA_EN are not limited to those shown in FIG. 6B. According to an exemplary embodiment of the inventive concept, the locations of the user data, the ECC parity, and the random I/O parity on the encoded data DATA_EN may be determined via conditional entropy. According to another exemplary embodiment of the inventive concept, the locations of the user data, the ECC parity, and the random I/O parity on the encoded data DATA_EN may be determined according to a Bhattacharyya parameter.

FIG. 7 illustrates a wafer bonding structure of a memory device according to an exemplary embodiment of the inventive concept. The memory device may have a structure in which a plurality of wafers are bonded with each other via wafer bonding. For convenience of explanation, FIG. 7 illustrates a memory device having a structure in which two wafers are bonded with each other. However, the inventive concept is not limited thereto. For example, the memory device may have a structure in which three or more wafers are bonded with each other.

For example, as shown in FIG. 7, the memory device may have a structure in which a first wafer 301 and a second wafer 302 are bonded with each other via wafer bonding.

The wafer bonding may be a method of manufacturing a plurality of wafers including a plurality of semiconductor chips and then bonding the plurality of wafers with one another on a wafer level. Bonding between wafers may be performed in various ways.

According to an exemplary embodiment of the inventive concept, the first wafer 301 may include various peripheral circuits including a control logic unit, e.g., control logic unit 350, and the second wafer 302 may include at least one memory cell array.

However, the inventive concept is not limited thereto, and the first wafer 301 may include at least one memory cell array and the second wafer 302 may include various peripheral circuits including a control logic unit.

For convenience of explanation, the memory device of FIG. 7 may have a structure in which the second wafer 302 is stacked on the first wafer 301. In some cases, the first wafer 301 may be referred to as a first layer and the second wafer 302 may be referred to as a second layer.

FIG. 8 illustrates a wafer bonding structure of a memory device according to an exemplary embodiment of the inventive concept. FIG. 8 will now be described with reference to FIG. 7.

A first wafer 301 and a second wafer 302 of FIG. 8 are illustrations of the first wafer 301 and the second wafer 302 of FIG. 7. In other words, according to an exemplary embodiment of the inventive concept, the first wafer 301 may include peripheral circuits, and the second wafer 302 may include at least one memory cell array.

The random I/O engine 370 may be formed on the first wafer 301 including the peripheral circuits. According to an exemplary embodiment of the inventive concept, the random I/O engine 370 may be formed on the first wafer 301 via a NAND end-of-line process or a logic process.

Because the memory device having a wafer bonding coupling structure includes the random I/O engine 370 on the first wafer 301, which is spatially separated from the second wafer 302, the capacity of data transmitted and/or received between the memory device and a memory controller may be reduced.

FIG. 9 is a perspective view illustrating a Cell-on-Peri (COP) structure of a memory device 300 according to an exemplary embodiment of the inventive concept. The memory device 300 may have a structure in which a second semiconductor layer L2 is stacked on a first semiconductor layer L1.

Referring to FIG. 9, the memory device 300 may include the first semiconductor layer L1 and the second semiconductor layer L2. The second semiconductor layer L2 may be stacked on the first semiconductor layer L1 in the third direction. In other words, the second semiconductor layer L2 may be disposed on the top of (or overlap) the first semiconductor layer L1. Alternatively, the first semiconductor layer L1 may be disposed on the top of the second semiconductor layer L2. The first semiconductor layer L1 may be referred to as a lower semiconductor layer, and the second semiconductor layer L2 may be referred to as an upper semiconductor layer.

According to an exemplary embodiment of the inventive concept, a control logic unit, a row decoder, or a page buffer may be formed on the first semiconductor layer L1, and a memory cell array may be formed on the second semiconductor layer L2. For example, the first semiconductor layer L1 may include a lower substrate, and various types of circuits may be formed on the first semiconductor layer L1 by forming, on the lower substrate, semiconductor devices, such as transistors, and patterns for wiring the semiconductor devices.

After circuits are formed on the first semiconductor layer L1, the second semiconductor layer L2 including a memory cell array may be formed. For example, the second semiconductor layer L2 may include an upper substrate. A memory cell array may be formed on the second semiconductor layer L2 by forming a plurality of gate conductive layers stacked on the upper substrate and a plurality of pillars penetrating through the plurality of gate conductive layers, each extending in a vertical direction with respect to the upper surface of the upper substrate (for example, the third direction). Patterns for electrically connecting the memory cell array (e.g., word lines WL and bit lines BL) and the circuits formed on the first semiconductor layer L1 to each other may be formed on the second semiconductor layer L2. For example, the bit lines BL may each extend in the first direction and may be arranged in the second direction. The word lines WL may each extend in the second direction and may be arranged in the first direction.

Accordingly, the memory device 300 may have a structure in which a control logic unit, a row decoder, a page buffer, or various other peripheral circuits and a memory cell array are arranged in a stacking direction (for example, the third direction), forming, a COP (Cell-On-Peri or Cell-Over-Peri) structure. By arranging circuits except for a memory cell array on the first semiconductor layer L1, the COP structure may effectively reduce the area occupied by a surface perpendicular to the stacking direction, and accordingly, may increase the number of memory cells integrated into the memory device 300.

It is to be understood that a plurality of pads may be arranged in the memory device 300 for electrical connection to the outside of the memory device 300. For example, a plurality of pads for a command, an address, and a control signal received from the outside of the memory device 300 may be provided, and a plurality of pads for inputting/outputting data may be provided. The pads may be arranged adjacent to a peripheral circuit that processes a signal received from or transmitted to the outside of the memory device 300, in the vertical direction (e.g., the third direction) or a horizontal direction (e.g., the first direction or the second direction).

FIG. 10 is a cross-sectional view illustrating a COP structure of a memory device according to an exemplary embodiment of the inventive concept. In particular, FIG. 10 schematically illustrates a cross-section of a memory device.

The memory device may include a first semiconductor layer L1 including peripheral circuits, and a second semiconductor layer L2 including a memory cell array. The memory device may have a structure in which the second semiconductor layer L2 is stacked on the first semiconductor layer L1.

The second semiconductor layer L2 may include an upper substrate U_SUB and a memory cell array arranged on the upper substrate U_SUB. The second semiconductor layer L2 may further include upper lines electrically connected to the memory cell array, and an upper insulation layer covering the memory cell array and the upper substrate U_SUB.

The upper substrate U_SUB may be located between the first semiconductor layer L1 and the memory cell array. The upper substrate U_SUB may be a support layer that supports the memory cell array. The upper substrate U_SUB may be referred to as a base substrate.

The memory cell array may include gate conductive layers GS stacked on the upper substrate U_SUB in the third direction. The gate conductive layers GS may include a ground select line GSL, word lines WL1, WL2, WL3, and WL4, and a string select line SSL. The gate conductive layers GS may include, for example, tungsten, tantalum, cobalt, nickel, tungsten silicide, tantalum silicide, cobalt silicide, or nickel silicide. As another example, the gate conductive layers GS may include polysilicon.

The ground select line GSL, the word lines WL1, WL2, WL3, and WL4, and the string select line SSL may be sequentially formed on the upper substrate U_SUB, and insulation layers 304 and 305 may be arranged on the bottom or top, respectively, of each of the gate conductive layers GS. For example, the insulation layer 304 may be disposed on the ground select line GSL and the insulation layer 305 may be disposed on the string select line SSL. The areas of the gate conductive layers GS may decrease in a direction away from the upper substrate U_SUB.

Although four word lines are shown in the present embodiment, a structure in which more or less than four word lines WL stacked between the ground select line GSL and the string select line SSL in a direction perpendicular to the upper substrate U_SUB may be formed. Alternatively, two or more ground select lines GSL and two or more string select lines SSL may be stacked in the vertical direction.

The memory cell array may include a plurality of pillars P that penetrate through the gate conductive layers GS and the insulation layers 304 and 305 in the third direction. For example, the plurality of pillars P may penetrate through the gate conductive layers GS and the insulation layers 304 and 305 to contact the upper substrate U_SUB. The plurality of pillars P may be arranged apart from each other at regular intervals.

For example, a surface layer S of each pillar P may include a silicon material doped with impurities or may include a silicon material undoped with impurities. The surface layer S may function as, for example, a channel region. The surface layer S may have a cup shape (or a shape of a cylinder having a bottom) extending in the third direction. An inside I of each pillar P may include an insulative material, such as Si oxide, or an air gap.

For example, the ground select line GSL and a portion of the surface layer S adjacent to the ground select line GSL may constitute a ground select transistor. The word lines WL1, WL2, WL3, and WL4 and portions of the surface layer S adjacent to the word lines WL1, WL2, WL3, and WL4 may constitute memory cell transistors. The string select line SSL and a portion of the surface layer S adjacent to the string select line SSL may constitute a string select transistor.

Drain regions DR may be formed on the plurality of pillars P. For example, the drain regions DR may include a silicon material doped with impurities. The drain regions DR may be channel pads. The drain regions DR may be electrically connected to the bit lines BL via one or more contacts.

An etch stop layer 306 may be formed on lateral walls of the drain regions DR. An upper surface of the etch stop layer 306 may be at the same level as that of each of the drain regions DR. The etch stop layer 306 may include an insulative material, such as Si nitride or Si oxide.

The first semiconductor layer L1 may include a lower substrate L_SUB, one or more peripheral transistors arranged on the lower substrate L_SUB, a lower insulation layer 303 covering the one or more peripheral transistors, and a contact plug penetrating through the lower insulation layer 303. For example, the peripheral transistors may be transistors that constitute a peripheral circuit, such as a control logic unit, a row decoder, a page buffer, or a common source line driver.

For example, the lower substrate L_SUB may be a semiconductor substrate including a semiconductor material, such as monocrystalline Si or monocrystalline Ge, or may be manufactured from a Si wafer.

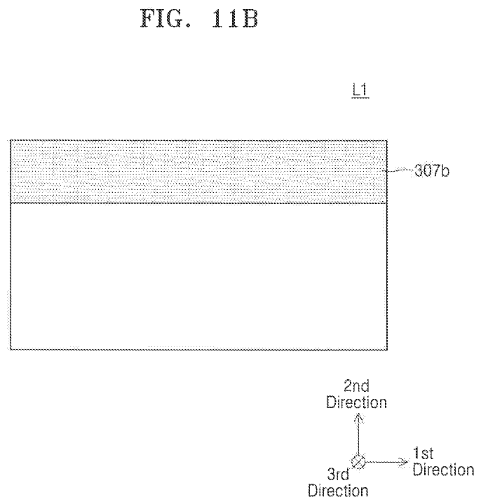

The random I/O engine 370 may be formed on the first semiconductor layer L1. For example, the random I/O engine 370 may be formed at various locations on the first semiconductor layer L1, as shown in FIGS. 11A through 11C. According to an exemplary embodiment of the inventive concept, the random I/O engine 370 may be formed on the first semiconductor layer L1 via a NAND end-of-line process or a logic process.

Because the memory device having a wafer bonding coupling structure includes the random I/O engine 370 on the first semiconductor layer L1 including peripheral circuits and spatially separated from the second semiconductor layer L2 including a memory cell array, the capacity of data transmitted and/or received between the memory device and a memory controller may be reduced.

FIGS. 11A through 11C are top views of the first semiconductor layer L1 of a memory device according to an exemplary embodiment of the inventive concept. In particular, FIGS. 11A through 11C illustrate top views of the first semiconductor layer L1 of FIGS. 9 and 10. FIGS. 11A through 11C illustrate first regions 307a, 307b, and 307c of the first semiconductor layer L1 on which the random I/O engine 370 is formed.

Referring to FIG. 11A, on the first semiconductor layer L1, the random I/O engine 370 may be formed in the first region 307a occupying a portion in the first direction and extending in the second direction. For example, the random I/O engine 370 may be formed near an edge of the first semiconductor layer L1.

Referring to FIG. 11B, on the first semiconductor layer L1, the random I/O engine 370 may be formed in the first region 307b occupying a portion in the second direction and extending in the first direction. For example, the random I/O engine 370 may be formed near a top portion of the first semiconductor layer L1.

Referring to FIG. 11C, the random I/O engine 370 may be formed at an arbitrary location on the first semiconductor layer L1. For example, the random I/O engine 370 may be formed near the middle of the first semiconductor layer L1.

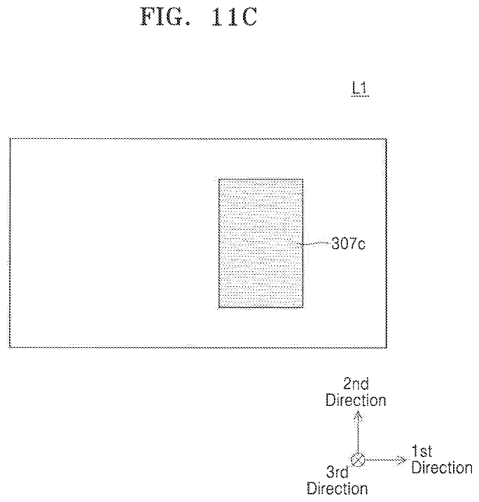

FIG. 12 is a flowchart of a data write operation of a storage device, according to an exemplary embodiment of the inventive concept. FIG. 12 will now be described with reference to FIG. 5. Descriptions of the memory controller 200 and the memory device 300 of FIG. 12 that are the same as those given above with reference to FIGS. 1, 2, and 5 will not be repeated herebelow.

In operation S110, the memory controller 200 may receive the data DATA from an external source. For example, the memory controller 200 may receive the data DATA from an external host. The data DATA may be user data. In addition, the memory controller 200 may receive, from the external host, a data write request and an address at which data is to be written. Although a case where the memory controller 200 receives data from an external source (for example, a host) is described in the present embodiment, the memory controller 200 may generate the data itself. It will be understood that the inventive concept to be described below is applicable to the data generated by the memory controller 200.

In operation S120, the memory controller 200 may transmit the data DATA to the memory device 300. For example, the memory controller 200 may provide the data DATA to the random I/O engine 370. In this case, the data DATA provided by the memory controller 200 to the random I/O engine 370 may be not-encoded data.

In operation S130, the random I/O engine 370 may generate the encoded data DATA_EN by performing random I/O encoding on the data DATA. For example, the random I/O encoder 372 of the random I/O engine 370 may generate the encoded data DATA_EN by encoding the data DATA by using the random I/O code.

In operation S140, the random I/O engine 370 may transmit the encoded data DATA_EN to the data I/O circuit 360. For example, the random I/O encoder 372 may provide the encoded data DATA_EN to the data I/O circuit 360.

In operation S150, the data I/O circuit 360 may write the received encoded data DATA_EN to a memory cell array.

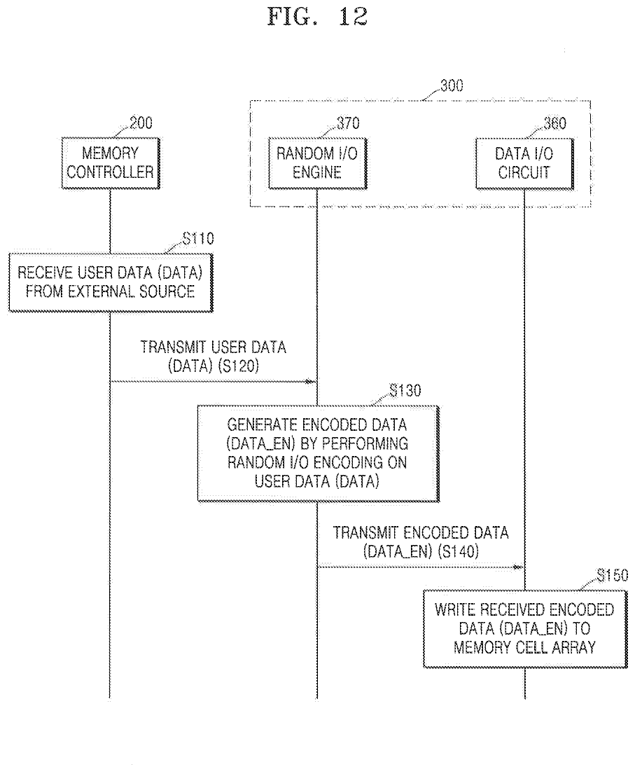

FIG. 13 is a flowchart of a data read operation of a storage device, according to an exemplary embodiment of the inventive concept. FIG. 13 will now be described with reference to FIG. 5. Descriptions of the memory controller 200 and the memory device 300 of FIG. 13 that are the same as those given above with reference to FIGS. 1, 2, and 5 will not be repeated herebelow.

In operation S210, the memory controller 200 may transmit a command and an address to the memory device 300 in response to an external request. For example, the memory controller 200 may transmit a command and an address to the memory device 300 in response to a data read request from an external host.

The memory device 300 may load the data of memory cells connected to a selected word line to a page buffer circuit, based on the command and the address provided by the memory controller 200. Data corresponding to a column address from among the data loaded to the page buffer circuit may be the internal read data DATA_IR.

In operation S220, the data I/O circuit 360 may obtain the internal read data DATA_IR from the page buffer circuit.

In operation S230, the data I/O circuit 360 may transmit the internal read data DATA_IR to the random I/O engine 370. For example, the data I/O circuit 360 may provide the internal read data DATA_IR to the random I/O decoder 374 of the random I/O engine 370.

In operation S240, the random I/O engine 370 may generate the decoded data DATA_DE by performing random I/O decoding on the internal read data DATA_IR. For example, the random I/O decoder 374 of the random I/O engine 370 may generate the decoded data DATA_DE by performing error correction while decoding the internal read data DATA_IR by using the random I/O code.

In operation S250, the random I/O engine 370 may transmit the decoded data DATA_DE to the memory controller 200. For example, the random I/O decoder 374 may transmit the decoded data DATA_DE as the read data DATA_R to the memory controller 200.

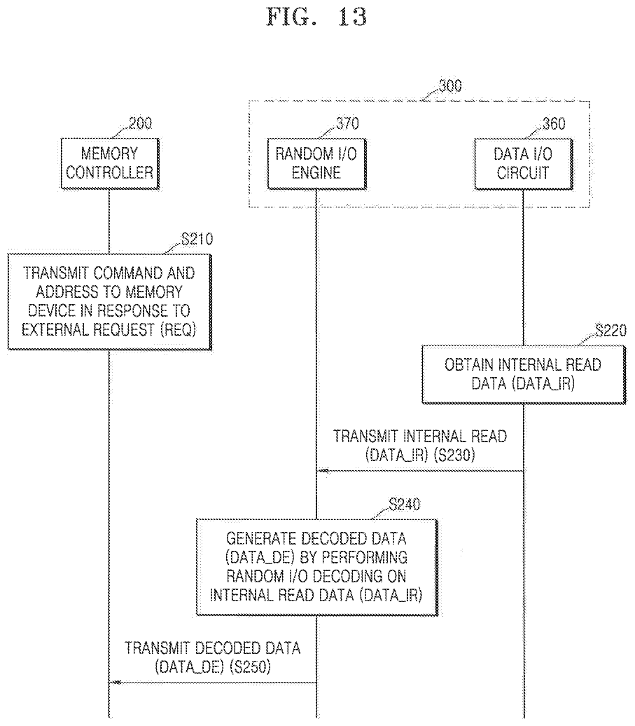

FIG. 14 is a block diagram of a data processing system 20 according to an exemplary embodiment of the inventive concept. FIG. 14 illustrates an embodiment in which the memory controller 200 includes an ECC encoder 382 and an ECC decoder 384 and performs an ECC operation. In other words, although the random I/O engine 370 performs error correction and ECC parity generation for the error correction in the descriptions given above with reference to FIGS. 1 through 13, exemplary embodiments of the inventive concept are not limited thereto.

The memory controller 200 may include the ECC encoder 382 and the ECC decoder 384. The memory device 300 may include the random I/O engine 370 for performing random I/O encoding and random I/O decoding. As described above with reference to FIGS. 1 through 13, the random I/O engine 370 may be formed on a peripheral circuit region spatially separated from a memory cell array, within the memory device 300.

In the write operation mode, the ECC encoder 382 may generate ECC encoded data DATA_E performing ECC encoding on data DATA in a user data state. For example, the ECC encoder 382 may generate the ECC encoded data DATA_E by encoding the data DATA by using an ECC. The ECC encoder 382 may provide the ECC encoded data DATA_E to the memory device 300.

The random I/O encoder 372 may generate the encoded data DATA_EN by encoding the ECC encoded data DATA_E by using the random I/O code.

In the read operation mode, the random I/O decoder 374 may generate random I/O decoded data DATA_RD by decoding the internal read data DATA_IR received from the data I/O circuit 360 by using the random I/O code. The random I/O decoder 374 may provide the random I/O decoded data DATA_RD to the memory controller 200.

The ECC decoder 384 may generate the decoded data DATA_DE by performing ECC decoding on the random I/O decoded data DATA_RD. For example, the ECC decoder 384 may generate the decoded data DATA_DE by decoding the random I/O decoded data DATA_RD by using an ECC.

In addition, in the embodiment of FIG. 14, since the random I/O engine 370 is formed in the memory device 300 instead of the memory controller 200, the capacity of data transmitted and/or received between the memory controller 200 and the memory device 300 may be reduced, and accordingly a data read-out time period may be reduced and power efficiency of the memory system may be increased.

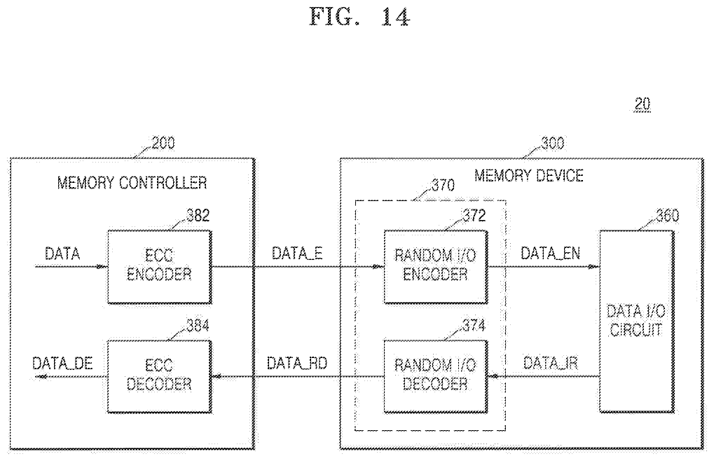

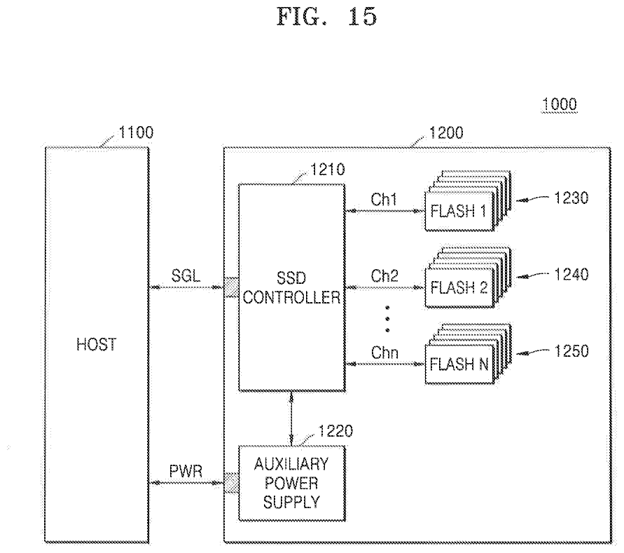

FIG. 15 is a block diagram of an SSD system 1000 according to an exemplary embodiment of the inventive concept. Referring to FIG. 15, the SSD system 1000 may include a host 1100 and an SSD 1200. The SSD 1200 may transmit or receive a signal SGL to or from the host 1100 through a signal connector and may receive power PWR from the host 1100 through a power connector. The SSD 1200 may include an SSD controller 1210, an auxiliary power supply 1220, and a plurality of flash memory devices 1230, 1240, and 1250. The flash memory devices 1230, 1240 and 1250 may be connected to the SSD controller 1210 via channels Ch1, Ch2 . . . Chn. The SSD 1200 may be implemented using the embodiments illustrated in FIGS. 1 through 14.

For example, according to the embodiments illustrated in FIGS. 1 through 14, each of the plurality of flash memory devices 1230, 1240, and 1250 may include a random I/O engine. Accordingly, compared with a case where no random I/O engines are implemented, the number of times sensing is performed in a data read operation may be reduced, and accordingly the read-out time period is reduced. In addition, and, compared with a case where the SSD controller 1210 includes a random I/O engine, the capacity of data transmitted and/or received between the SSD controller 1210 and the flash memory devices 1230, 1240, and 1250 may be reduced, and accordingly the data read-out time period may be reduced and power efficiency of the SSD 1200 may be increased.

While the inventive concept has been particularly shown and described with reference to exemplary embodiments thereof, it will be understood that various changes in form and details may be made thereto without departing from the spirit and scope of the inventive concept as described in the following claims.

1. A storage device, comprising:
a memory controller configured to output user data received from outside of the storage device in a write operation mode and receive read data in a read operation mode; and
a memory device comprising a memory cell array and a random input and output (I/O) engine, the random I/O engine configured to encode the user data provided from the memory controller using a random I/O code, in the write operation mode, and to generate the read data by decoding internal read data read by a data I/O circuit from the memory cell array using the random I/O code, in the read operation mode.

2. The storage device of claim 1, wherein
the memory device has a first wafer including the memory cell array and a second wafer including a peripheral circuit bonded with each other, and
the random I/O engine is formed on the second wafer.

3. The storage device of claim 1, wherein
the memory device has a Cell-on-Peri (COP) structure in which a second layer including the memory cell array is stacked on a first layer including a peripheral circuit, and
the random I/O engine is formed on the first layer.

4. The storage device of claim 1, wherein the random I/O engine comprises:
a random I/O encoder configured to encode the user data using the random I/O code in the write operation mode; and
a random I/O decoder configured to correct an error while decoding the internal read data using the random I/O code in the read operation mode.

5. The storage device of claim 1, wherein the random I/O engine is configured to perform error correction on the internal read data using an error correction code (ECC) in the read operation mode.

6. The storage device of claim 1, wherein the memory device comprises the memory cell array comprising multi-level cells each storing two or more bits of data, and wherein the memory device is configured to read data from a selected memory cell via one sensing operation in the read operation mode.

7. The storage device of claim 1, wherein the user data provided by the memory controller to the memory device is not-encoded.

8. The storage device of claim 1, wherein
the random I/O code includes a polar code, and
encoded data obtained by the random I/O engine comprises the user data, an error correction code (ECC) parity, and a random I/O parity.

9. The storage device of claim 1, wherein the random I/O code engine is formed on the memory device via a NAND end-of-line process or logic process.

10. A memory device comprising a plurality of layers, the memory device comprising:
a first layer comprising a plurality of memory cells; and
a second layer comprising a control logic unit and a random input and output (I/O) engine,
wherein the random I/O engine comprises:
a random I/O encoder configured to encode user data received from outside of the memory device using a random I/O code; and
a random I/O decoder configured to decode internal read data obtained from the memory device using the random I/O code.

11. The memory device of claim 10, wherein
the first layer is a first wafer comprising the plurality of memory cells,
the second layer is a second wafer comprising the control logic unit and the random I/O engine, and
the first wafer and the second wafer are bonded with each other.

12. The memory device of claim 10, wherein the memory device has a Cell-on-Peri (COP) structure in which the second layer is stacked on the first layer.

13. The memory device of claim 10, wherein
the memory device further comprises a data I/O circuit configured to provide data to a page buffer circuit in a write operation mode of the memory device, and
the random I/O encoder is configured to generate encoded data having a larger capacity than the user data by encoding the user data using the random I/O code and provide the encoded data to the data I/O circuit, in the write operation mode.

14. The memory device of claim 13, wherein the encoded data comprises the user data, an error correction code (ECC) parity, and a random I/O parity.

15. The memory device of claim 10, wherein
the memory device further comprises a data I/O circuit configured to provide the internal read data to a page buffer circuit in a read operation mode of the memory device, and
the random I/O decoder is configured to generate decoded data having a smaller capacity than the internal read data by decoding the internal read data by using the random I/O code and output the decoded data to the outside of the memory device, in the read operation mode.

16. A storage device, comprising:
a memory device comprising a memory cell array including a plurality of memory cells, and a peripheral circuit region spatially separated from the memory cell array; and
a memory controller configured to control an operation of the memory device,
wherein the memory device comprises a random input and output (I/O) engine formed on the peripheral circuit region and configured to encode data received from the memory controller and decode data that is to be transmitted to the memory controller.

17. The storage device of claim 16, wherein the memory device has a first wafer including the memory cell array and a second wafer including the peripheral circuit region bonded with each other.

18. The storage device of claim 16, wherein the memory device has a Cell-on-Peri (COP) structure in which a second layer including the memory cell array is stacked on a first layer including the peripheral circuit region.

19. The storage device of claim 16, wherein the random I/O engine comprises:
a random I/O encoder configured to encode user data received from the memory controller using a random I/O code, in a write operation mode; and
a random I/O decoder configured to correct an error while decoding internal read data provided by a data I/O circuit of the memory device using the random I/O code, in a read operation mode.

20. The storage device of claim 16, wherein the memory device comprises a memory cell array comprising multi-level cells each storing two or more bits of data, and wherein the memory device is configured to read data from a selected memory cell via one sensing operation in a read operation mode.

21-22. (canceled)
